(19) United States
(12) Patent Application Publication
(10) Pub. No.: US 2007/0222006 A1
(43) Pub. Date: Sep. 27, 2007

(54) Micromechanical component and corresponding manufacturing method

(76) Inventors: Heribert Weber, Nuertingen (DE); Christoph Schelling, Reutlingen (DE)

Correspondence Address: KENYON & KENYON LLP, ONE BROADWAY, NEW YORK, NY, 10004, US

(21) Appl. No.: 11/700,709

(22) Filed: Jan. 30, 2007

(30) Foreign Application Priority Data
Jan. 31, 2006 (DE) 10 2006 004 287.5

(51) Int. Cl. H01L 29/82

(52) U.S. Cl. 257/414

(57) ABSTRACT

A micromechanical component which includes a substrate; a first rigid electrode system situated on or in the substrate; a second electrode system suspended on the substrate; an intermediate space provided between the first electrode system and the second electrode system; the second electrode system being mounted on the suspension post in an elastically deflectable manner with respect to the first electrode system such that the capacitance of a capacitor formed by the first electrode system, the second electrode system, and the intermediate space may be modified.

### FIELD OF THE INVENTION

The present invention relates to a micromechanical component and a corresponding manufacturing method.

### BACKGROUND INFORMATION

Although applicable in principle to any micromechanical components or manufacturing methods for same, the present invention and the principle upon which it is based are explained with reference to microphone components.

Graphite-based electret microphones (ECM—electret condenser microphone+) are widely used. Manufactured in the billions, they are installed in cordless telephones, for example. However, such ECM microphones are extremely sensitive to temperature and are incompatible with current manufacturing and connection techniques, such as surface-mounted device (SMD) soldering, for example. They require additional cost-intensive assembly steps. For this reason, there have been intensive efforts to manufacture microphones from silicon, using micromechanical technology. Such an implementation of a semiconductor-based microphone also offers the option of integrated signal processing on the same chip.

Because of the advantages regarding power consumption, most approaches have concentrated on micromechanical silicon microphones using the capacitive transducer principle. Of the known approaches, practically all provide two superposed diaphragms above a substrate opening (see, for example, International Application Nos. WO 03/098969, WO 03/068668, and WO 03/055271). In this type of design, both diaphragms are suspended at their periphery. One of the diaphragms is rigid and perforated, and the other is flexible and has very few or no perforation holes.

European Application EP 1 012 547 B1 describes a miniaturized semiconductor capacitor microphone based on a flat bending beam positioned above a substrate opening.

European Application EP 1 443 017 A1 describes the approach of a differential capacitive microphone without a substrate opening below the diaphragms, and a microphone composed of a specialized bending beam system. The diaphragms or bending beams are made of at least one metal layer.

A micromechanical component having a substrate, a cavity provided in the substrate, and a diaphragm provided on the surface of the substrate which is located above the cavity is described in German Patent Application DE 10 2004 050764. The diaphragm has a height modulation above the cavity with respect to the top side of the surrounding substrate.

### SUMMARY

A micromechanical component according to an example embodiment of the present invention may have the advantage that short-term pressure fluctuations, in particular sound waves, may be accurately detected, and assembly may be performed easily and reliably.

A central suspension post or a frame may be used to fix the bending beam or the bending beam segments of the upper electrode system, preferably via one or more bending spring elements. The spring elements between the bending beam and the suspension post or frame provide great flexibility for vertical motions of the bending beam. Structuring holes are preferably used at the same time for fluid attenuation of the system. The dynamic pressure used for the measurement builds up between the top and bottom of the bending beam.

The external shape, segmentation, perforation, and layer thickness of the bending beam or bending beam segments determine the general characteristics of the micromechanical component, in particular its sensitivity, frequency response, directional sensitivity, etc. The bending beam or bending beam segments may have a planar design. Nonplanar structures such as a meandering structure, for example, may offer the possibility of reducing the spring stiffness. To prevent warping due to layer stresses or layer stress gradients, special measures such as corrugation, for example, may be provided. The thickness of the insulating sacrificial layer and thus the distance between the upper and lower electrode systems determines the measured capacitance. The distance should be selected to be as small as possible, and the capacitance, as large as possible. The parasitic capacitance of the system, which should be selected to be as large as possible, may be set via the thickness of an optional additional insulating layer, in particular an oxide layer, below the rigid lower electrode system. Alternatively, the counterelectrodes of the lower rigid electrode system may be under-etched, at least in part.

An electrical voltage may be applied between the counterelectrodes of the lower electrode system and the bending beam for the upper electrode system, thereby decreasing the distance between same and correspondingly increasing the sensitivity.

A comb structure may be applied to the outer edge of the bending beam segments and the inner edge of an optional, rigidly applied peripheral third electrode structure. This allows a differential capacitive measurement of the bending beam deflection in only two planes. In addition, an electrical voltage may be applied via such a third electrode system, thereby enabling microphone characteristics to be influenced (smoothing out bending beams, setting sensitivity, etc.).

In addition, particular advantages may include directional recognition via a possible azimuthal segmentation of the electrode systems, high sensitivity of the bending beam by suspension via spring elements at a few points, and omission of openings passing through the substrate, which may be important for cost-effective manufacture and simplified assembly.

According to one preferred refinement, the first electrode system has multiple electrically decoupled, circular segment-shaped electrodes which are symmetrically situated around the suspension post.

According to a further preferred refinement, the second electrode system has multiple electrically coupled, circular segment-shaped electrodes which are symmetrically suspended around the suspension post, essentially congruent with the corresponding circular segment-shaped electrodes for the first electrode system.

According to a further preferred refinement, the first electrode system and the second electrode system are patterned from a first and second conductive layer, respectively.

According to a further preferred refinement, a cover plate is provided above the second electrode system which determines the entry of fluid media into the intermediate space. In this manner density waves may be effectively conducted into the intermediate space.

### BRIEF DESCRIPTION OF THE DRAWINGS

Exemplary embodiments of the present invention are illustrated in the figures, and are explained in greater detail below.

FIGS. 1a, b show schematic horizontal cross-sectional views of a micromechanical component according to a first example embodiment of the present invention, FIG. 1a showing a flat cross section of the lower electrode region and FIG. 1b showing a cross section of the upper electrode region.

FIGS. 2a, b, c show schematic vertical cross-sectional views of the micromechanical component according to the first embodiment of the present invention, FIG. 2a showing a view along lines A-A′ and B-B′ in FIGS. 1a, b, FIG. 2b showing a view along lines C-C′ and C1-C1′ in FIGS. 1a, b, and FIG. 2c showing a view along lines A1-A1′ and B1-B1′ in FIGS. 1a, b.

FIGS. 3a-e show successive process steps of a method for manufacturing the micromechanical component according to the first embodiment of the present invention, in schematic vertical cross-sectional views along lines A-A′ and B-B′ and along lines C-C′ and C1-C1′ in FIGS. 1a, b.

FIG. 4 shows a schematic top view of a micromechanical component according to a second example embodiment of the present invention.

FIG. 5 shows a schematic vertical cross-sectional view of the micromechanical component according to the second embodiment of the present invention, along line D-D′ in FIG. 4.

FIGS. 6a-d show successive process steps of a method for manufacturing the micromechanical component according to the second embodiment of the present invention, in schematic vertical cross-sectional views along line D-D′ in FIG. 4.

FIG. 7 shows a sectional schematic top view of a micromechanical component according to a third example embodiment of the present invention.

FIG. 8 shows a sectional schematic top view of a micromechanical component according to a fourth example embodiment of the present invention.

FIG. 9 shows a schematic top view of a micromechanical component according to a fifth example embodiment of the present invention.

FIG. 10 shows a schematic vertical cross-sectional view of the micromechanical component according to the fifth embodiment of the present invention, along line B2-B2′ in FIG. 12.

FIG. 11 shows a schematic vertical cross-sectional view of the micromechanical component according to the fifth embodiment of the present invention, along line B3-B3′ in FIG. 12.

FIG. 12 shows a schematic horizontal cross-sectional view of a micromechanical component according to the fifth embodiment of the present invention, through the movable electrode region.

### DETAILED DESCRIPTION OF EXAMPLE EMBODIMENTS

In the figures, identical or functionally equivalent components are designated by the same reference numerals.

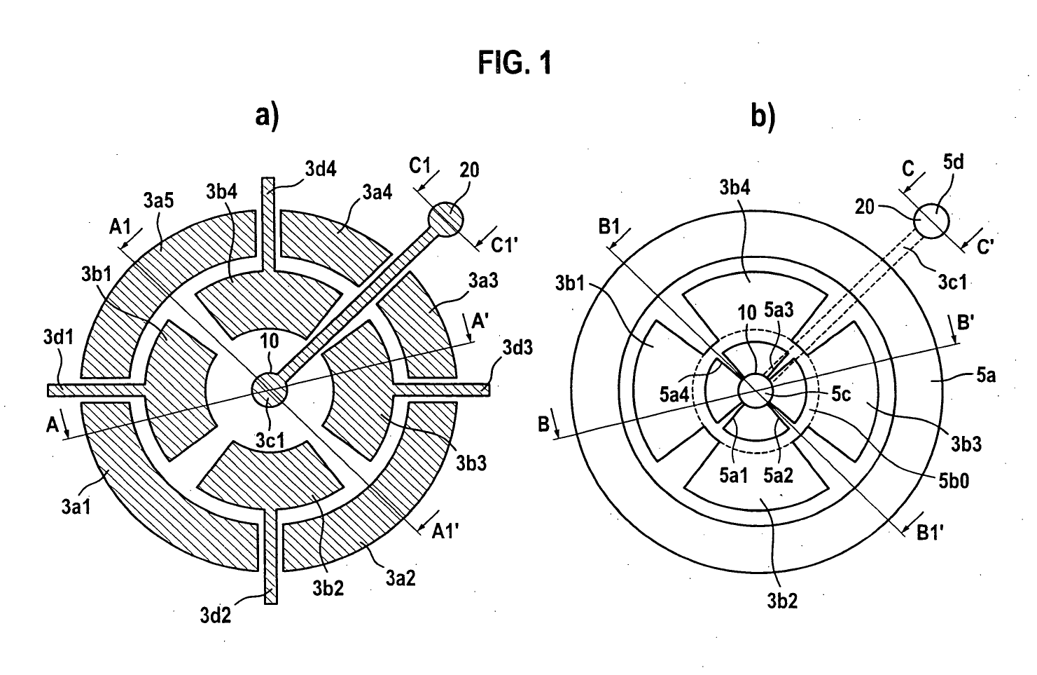

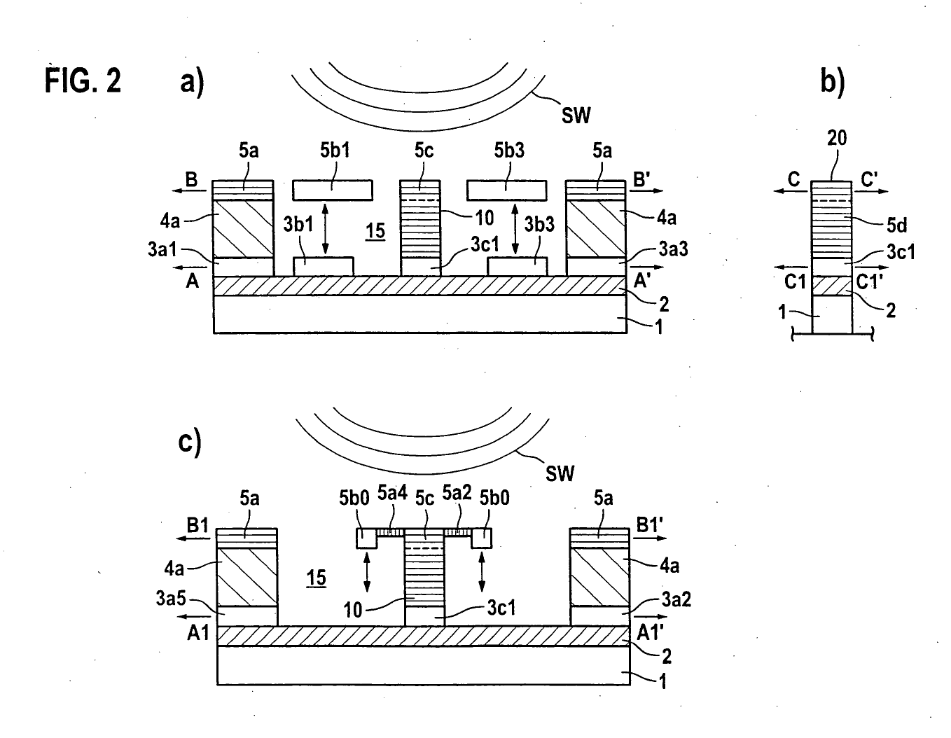

FIGS. 1a, b show schematic horizontal cross-sectional views of a micromechanical component according to a first example embodiment of the present invention, FIG. 1a showing a flat cross section of the lower electrode region and FIG. 1b showing a cross section of the upper electrode region; FIGS. 2a, b, c show corresponding schematic vertical cross-sectional views of the micromechanical component according to the first embodiment of the present invention, FIG. 2a showing a view along lines A-A′ and B-B′ in FIGS. 1a, b, FIG. 2b showing a view along lines C-C′ and C1-C1′ in FIGS. 1a, b, and FIG. 2c showing a view along lines A1-A1′ and B1-B1′ in FIGS. 1a, b.

The flat cross-sectional view of FIG. 1a shows a first lower electrode system having four circular segment-shaped rigid lower electrodes 3b1, 3b2, 3b3, 3b4 having respective lead sections 3d1, 3d2, 3d3, 3d4. FIG. 1a also illustrates the lowest section of a central suspension post 10, together with a corresponding lead section 3c1 having a rectangular center region which on one side ends in a lower circular section of a contact plug 20 and on the other side ends in a lower circular section of central suspension post 10.

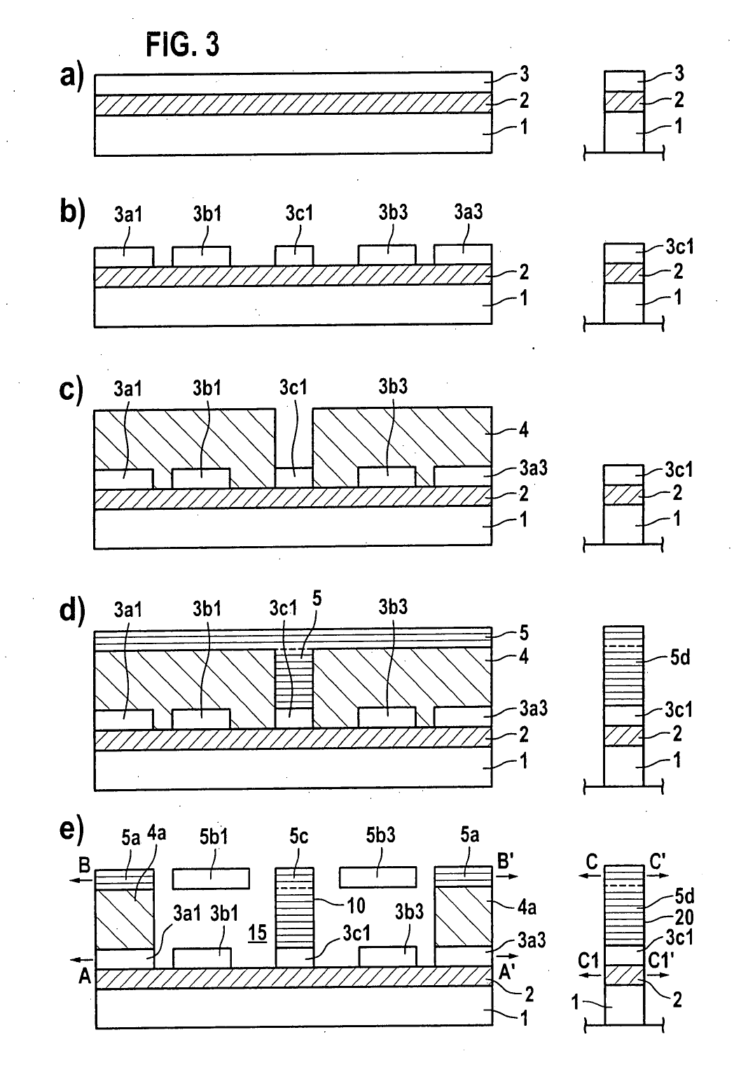

Furthermore, reference numerals 3a1, 3a2, 3a3, 3a4, 3a5 designate frame segments which surround electrodes 3b1, 3b2, 3b3, 3b4 for the lower electrode system and which are interrupted only in the region of lead sections 3d1, 3d2, 3d3, 3d4. All elements illustrated in FIG. 1a are manufactured in one plane made of a single conductive layer 3 (see FIG. 3a) composed of polysilicon, for example.

FIG. 1b shows a flat cross-sectional view of a second upper electrode system. The upper electrode system has four circular segment-shaped deflectable electrodes 5b1, 5b2, 5b3, 5b4 in the form of bending beams which are connected via an annular segment 5b0. Annular segment 5b0 is connected to the upper section of suspension post 10 via bending springs 5a1, 5a2, 5a3, 5a4. Suspension post 10 is formed by a conductive plug 5c which rests on the lower circular section of lead section 3c1 for central suspension post 10. The four circular segment-shaped, deflectable electrodes 5b1, 5b2, 5b3, 5b4 in the undeflected state are situated generally congruently above electrodes 3b1, 3b2, 3b3, 3b4 for the lower electrode system, separated by an intermediate space 15 (see FIGS. 2a, b). As also shown in FIG. 1b, contact plug 20 is formed by conductive plug 5d, which rests on the lower circular section of lead section 3c1 for central suspension post 10. A third peripheral rigid electrode system in the form of an annular ring 5a is provided above frame segments 3a1, 3a2, 3a3, 3a4, 3a5, and is separated from same via an annular insulating layer region 4a (see FIGS. 2a, b).

Elements 5a, 5b1, 5b2, 5b3, 5b4, 5c, and 5d are likewise patterned from a single conductive layer made of polysilicon, for example (see FIG. 3d).

As seen from the vertical sectional view of FIG. 2a, intermediate space 15 which is filled with a fluid, ambient air, for example, is located between the four circular segment-shaped deflectable electrodes 5b1, 5b2, 5b3, 5b4 and the four rigid circular segment-shaped electrodes 3b1, 3b2, 3b3, 3b4. Annular insulation region 4a, made of silicon oxide, for example, is seen between third annular electrode system 5a and frame segments 3a1, 3a2, 3a3, 3a4, 3a5. Also seen in FIG. 2a is a continuous insulating layer 2, above substrate 1 and below the lower electrode system, which in the present case is likewise made of silicon oxide.

The vertical cross section of FIG. 2c shows the suspension of annular electrode section 5b0 on central suspension post 10 via thin bending springs 5a2, 5a4. Such a suspension allows electrodes 5b1, 5b2, 5b3, 5b4 for the upper electrode system to be slightly deflectable when impinged on by sound waves SW.

Electrical contacting of the four circular segment-shaped deflectable electrodes 5b1, 5b2, 5b3, 5b4 is achieved by contact plug 20 via lead section 3c1, central suspension post 10, bending springs 5a1, 5a2, 5a3, 5a4, and annular electrode section 5b0.

The azimuthal electrical subdivision of electrodes 3b1, 3b2, 3b3, 3b4 for the lower electrode system allows impinging sound waves SW to be detected in a directionally sensitive manner. The double arrows in FIGS. 2a, 2b show the directions of deflection of the upper electrode system.

FIGS. 3a-e show successive process steps of a method for manufacturing the micromechanical component according to the first example embodiment of the present invention, in schematic vertical cross-sectional views along lines A-A′ and B-B′ and along lines C-C′ and C1-C1′ in FIGS. 1a, b.

The left and right regions in FIGS. 3a-e correspond to the illustrations of FIGS. 2a (left region) and 2b (right region), respectively. Since the illustration in FIG. 2c is clear, the manufacture in a sectional view according to FIG. 2c has not been additionally illustrated in FIGS. 3a-e.

With reference to FIG. 3a, first an insulating layer 2 made of silicon oxide and/or silicon nitride or a combination of both is applied to substrate 1 made of silicon. A first conductive layer 3 made of polysilicon is deposited thereon.

As illustrated in FIG. 3b, first conductive layer 3 made of polysilicon is then patterned to produce electrodes 3b1, 3b2, 3b3, 3b4 together with lead sections 3d1, 3d2, 3d3, 3d4, frame elements 3a1, 3a2, 3a3, 3a4, 3a5, and lead section 3c1 for central suspension post 10. This patterning is performed using known photolithographic methods and therefore is not explained further. The patterning results in the state according to FIG. 1.

Furthermore, with reference to FIG. 3c a second insulating layer 4 made of silicon oxide is then deposited over patterned conductive layer 3, made of polysilicon, and first insulating layer 2. The regions of insulating layer 4 situated above the circular regions (see FIG. 1) of lead section 3c1 are then photolithographically removed in the locations in which central suspension post 10 and contact plug 20 are to be provided.

As illustrated in FIG. 3d, a second conductive layer 5 made of polysilicon is then deposited over the structure. Second conductive layer 5 is then repolished, the top side of second insulating layer 4 made of silicon oxide being used as a polishing stop.

As a result of this repolishing, plug-like connecting sections 5c, 5d for central suspension post 10 and contact plug 20, respectively, are completed within insulating layer 4. Second conductive layer 5 is then deposited once again on the top side of the structure, resulting in the state according to FIG. 3d. Repolishing may be omitted, if necessary, in which case the redeposition of the layer is not performed.

Continuing with reference to FIG. 3d, photolithographic patterning of second conductive layer section 5 is then carried out to form electrodes 5b1, 5b2, 5b3, 5b4, annular electrode section 5b0, bending springs 5a1, 5a2, 5a3, 5a4, the topmost sections of central suspension post 10 and contact plug 20, and annular third electrode system 5a, as illustrated in FIG. 1b.

In this regard it is noted that the thickness of bending springs 5a1, 5a2, 5a3, 5a4 is less than the thickness of electrodes 5b1, 5b2, 5b3, 5b4 and annular electrode section 5b0, and may be influenced in particular by the geometric perforations and the electrical voltages for sacrificial layer etching. When the bending springs are designed in a meandering shape, the thickness of the bending springs may be the same as that of the electrodes.

Insulating layer 4 for forming intermediate space 15 is then partially removed by an etching process. A perforation (not illustrated here) in the upper electrode system is used to accurately determine where insulating layer 4 should be removed. Thus, in particular vertical edges of insulation region 4a may be achieved above frame segments 3a1, 3a2, 3a3, 3a4, 3a5.

Lastly, the process state of FIG. 3e corresponds to the state illustrated in FIGS. 2a, b.

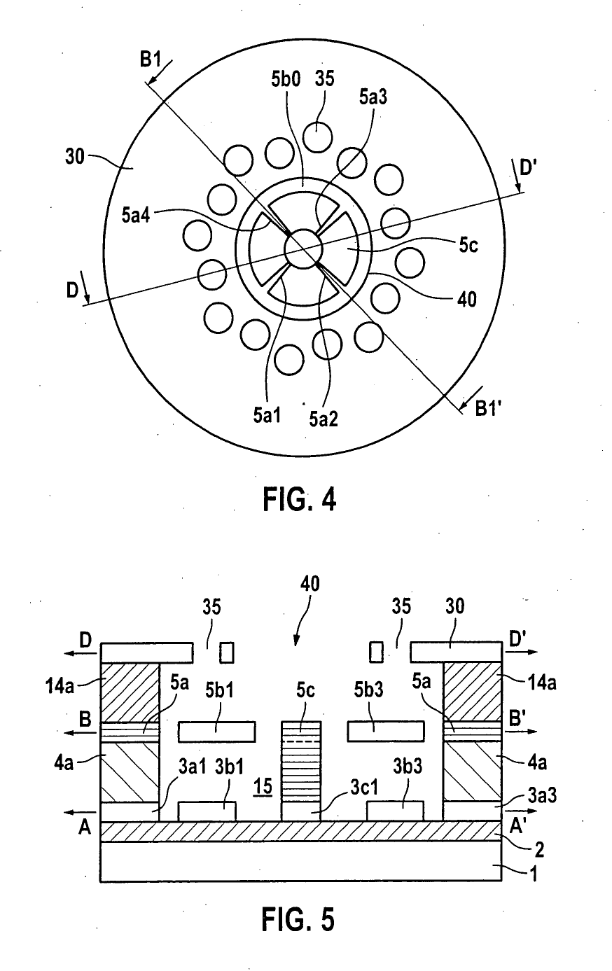

FIG. 4 shows a schematic top view of a micromechanical component according to a second example embodiment of the present invention, and FIG. 5 shows a schematic vertical cross-sectional view of the micromechanical component according to the second embodiment of the present invention, along line D-D′ in FIG. 4.

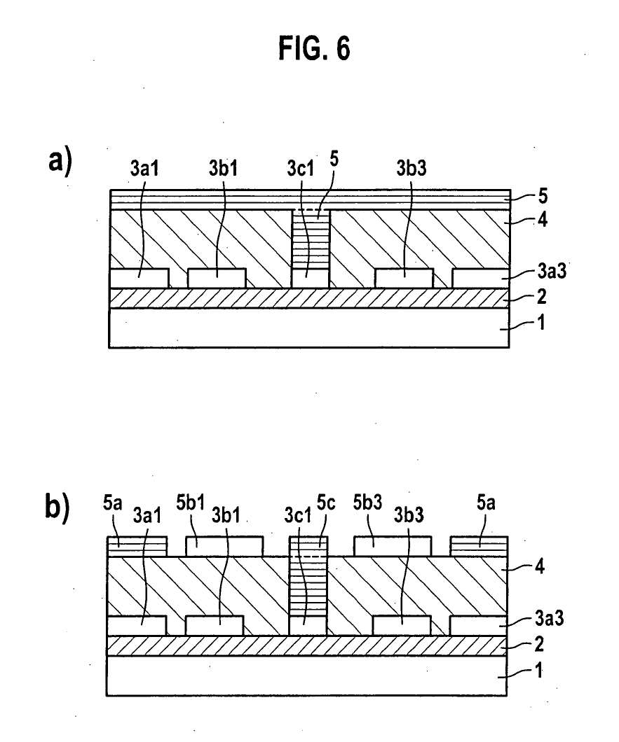

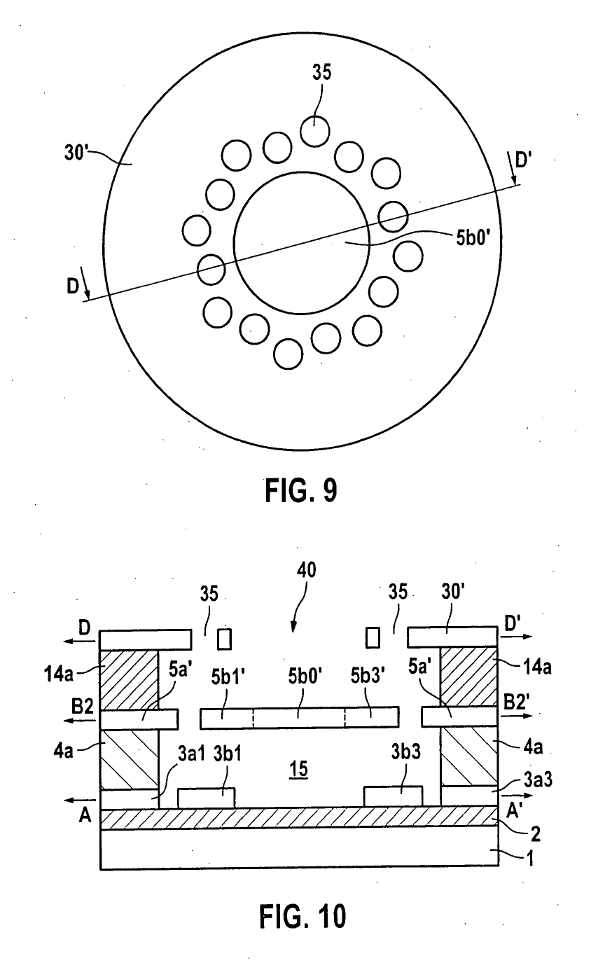

In the second embodiment shown in FIGS. 4 and 5, a cover plate 30 having through holes 35 for density waves, in particular sound waves, is also provided on top of the upper electrode system, above the frame segments, i.e., third electrode system 5a. Cover plate 30 is composed of a nonconductive layer (see FIG. 6d) from which through holes 35 and a central through hole 40 are patterned. Cover plate 30 is separated from the frame segments, i.e., third electrode system 5a, via an additional insulating layer 14a. Cover plate 30 may also be made of a conductive insulated or noninsulated layer, and may be used as an additional electrode (see FIGS. 9 through 13).

FIGS. 6a-d show successive process steps of a method for manufacturing the micromechanical component according to the second embodiment of the present invention, in schematic vertical cross-sectional views along line D-D′ in FIG. 4.

The process state of FIG. 6a corresponds to the process state of FIG. 3d, and the sectional view corresponds to FIG. 2a. Subsequent to the state according to FIG. 6a, electrodes 5b1, 5b2, 5b3, 5b4, 5b0, bending springs 5a1, 5a2, 5a3, 5a4, plug section 5c for suspension post 10, and plug section 5d for contact plug 20 are patterned from second conductive layer 5 according to FIG. 6b.

Third insulating layer 14 made of silicon oxide is subsequently deposited on top of the resulting structure. The nonconductive layer, silicon nitride, for example, for cover plate 30 is then deposited on top of third insulating layer 14 and patterned. This is followed by sacrificial layer etching, in which second insulating layer 4 and third insulating layer 14 are removed in the regions where intermediate space 15 for the sound detection is to be provided between the lower electrode system and the upper electrode system. This ultimately results in the process state of FIG. 6d.

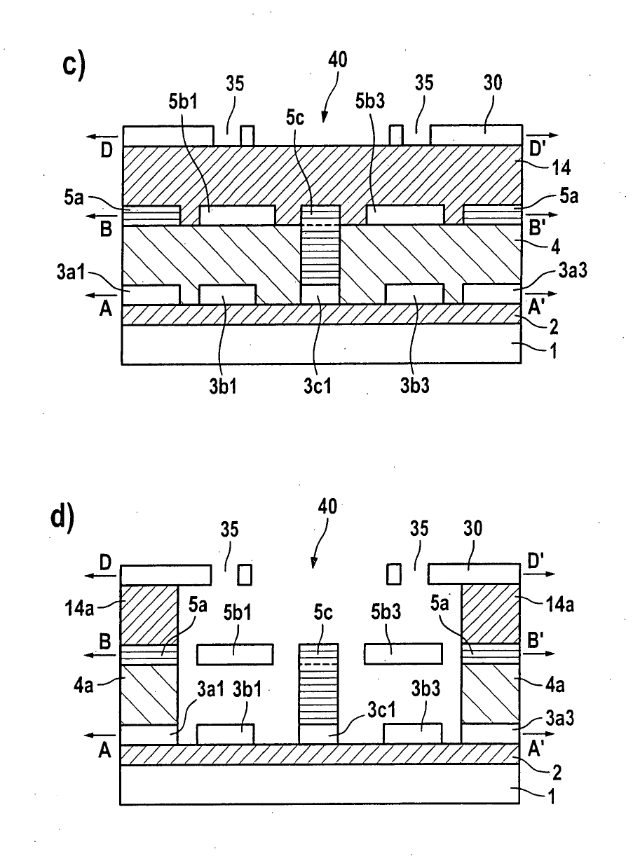

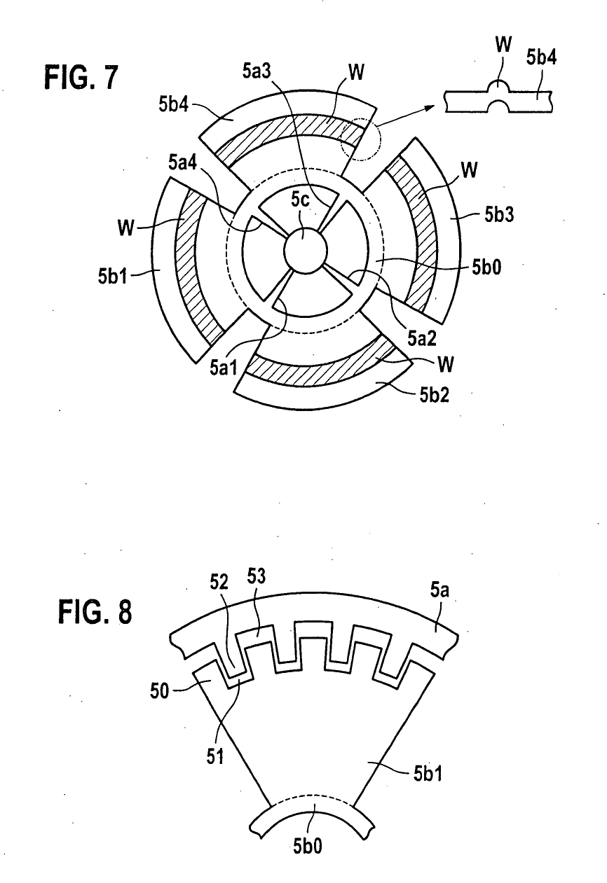

FIG. 7 shows a sectional schematic top view of a micromechanical component according to a third example embodiment of the present invention.

In the third embodiment according to FIG. 7, corrugation of upper deflectable electrodes 5b1, 5b2, 5b3, 5b4 is provided, in the present case as a design in the shape of an undulating elevation W. Also possible is a corrugation of bending springs 5a1, 5a2, 5a3, 5a4 for the relaxation of stress gradients and in-plane stress, a corrugation composed of a superimposition of concentric radial undulations and azimuthal undulations having proven to be particularly suitable. Various mechanical and fluid dynamic characteristics may be imparted by varying the perforation or corrugation of the bending beam segments.

FIG. 8 shows a sectional schematic top view of a micromechanical component according to a fourth example embodiment of the present invention.

In the fourth embodiment according to FIG. 8, a comb structure having teeth 52 and indentations 53 is also provided on circumferential third electrical electrode system 5a′, the comb structure being interlocked, i.e., engaged, with a corresponding comb structure, having teeth 50 and indentations 51, provided on electrodes 5b1′, etc. for the upper electrode system.

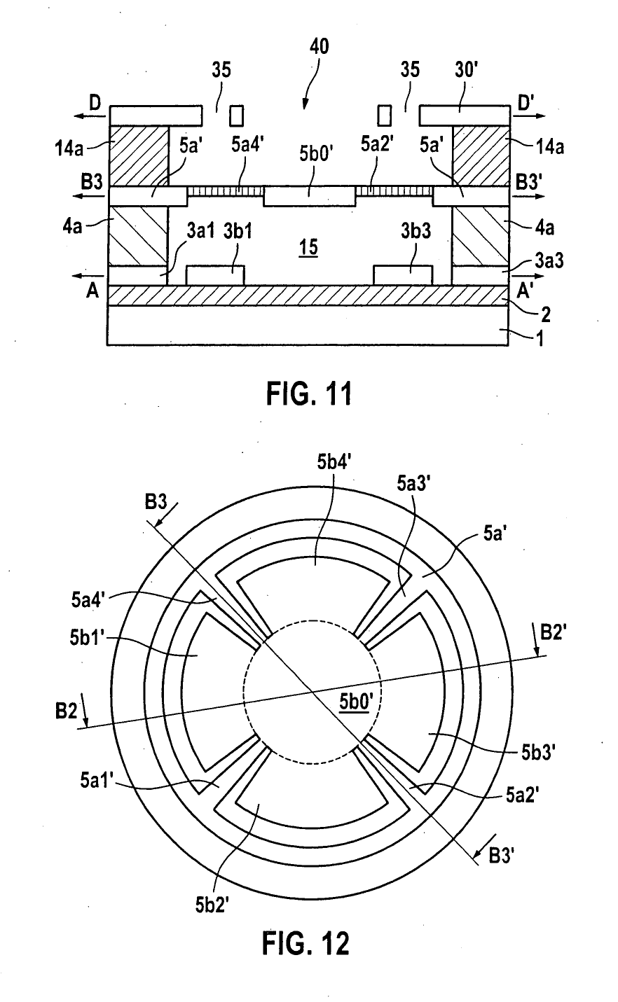

FIG. 9 illustrates a schematic top view of a micromechanical component according to a fifth embodiment of the present invention, and FIGS. 10 and 11 show sectional vertical cross-sectional views of the micromechanical component according to the fifth embodiment of the present invention, specifically, along line B2-B2′ and line B3-B3′ in FIG. 12, and FIG. 12 shows a schematic horizontal cross-sectional view of a micromechanical component according to the fifth embodiment of the present invention, through the movable electrode region.

In the fifth embodiment according to FIGS. 9 through 12, a conductive cover plate 30′ having through holes 35 for density waves, in particular sound waves, is provided on top of the upper electrode system, above the frame segments. Cover plate 30′ is composed of a conductive layer made of silicon, from which through holes 35 and a central through hole 40 are patterned. Cover plate 30′ is separated from the frame segments via additional insulating layer 14a. In this embodiment the cover plate forms an additional electrode, which together with movable electrodes 5b1′, 5b2′, 5b3′, 5b4′ and lower rigid electrodes 3b1, 3b2, 3b3, 3b4 results in a differential capacitor system.

As seen in FIGS. 10 through 12, in this fifth embodiment no central suspension post is provided, and instead movable electrodes 5b1′, 5b2′, 5b3′, 5b4′ are suspended on a circular center electrode region 5b0′, which in turn is suspended via bending springs 5a1′, 5a2′, 5a3′, 5a4′ on a frame element 5a′ which is formed from the same layer. Frame element 5a′ is anchored on substrate 1 via insulating layer 4a, elements 4a, 3a1-3a5, and insulating layer 2.

Although in this case the present invention has been described with reference to preferred exemplary embodiments, the present invention is not limited thereto and may be modified in a variety of ways.

For example, the electrode geometry and the materials are arbitrary, and are not limited to the examples shown. The material of the two conductive layers is not limited to polysilicon, but, rather, may in particular also be metal.

### LIST OF REFERENCE NUMERALS

3a1-3a5 Frame segment
3d1-3d5 Lead sections
3b1-3b4 Lower electrode regions
10 Suspension post
20 Contact plug
5b1-5b4 Upper electrode sections
5b1′-5b4′ Upper electrode sections
5b0 Annular electrode section
5b0′ Annular electrode section
5a1-5a4 Bending springs
5a1′-5a4′ Bending springs
5c Contact plug of 10
5d Contact plug of 20
3c1 Lead section
5a Annular third electrode system
5a′ Frame element
15 Intermediate space
1 Substrate
2 First insulating layer
4, 4a Second insulating layer
14, 14a Third insulating layer
30, 30′ Cover plate
35 Through hole
40 Central through hole
W Undulating corrugation
51-53 Comb structure

What is claimed is:

1. A micromechanical component, comprising:
a substrate;
a first rigid electrode system situated one of on or in the substrate;
a second electrode system suspended on the substrate, an intermediate space being between the first electrode system and the second electrode system;
wherein the second electrode system is suspended on the substrate in an elastically deflectable manner with respect to the first electrode system such that a capacitance of a capacitor formed by the first electrode system, the second electrode system, and the intermediate space is modifiable.

2. The micromechanical component as recited in claim 1, further comprising:
a suspension post provided on the substrate via which the second electrode system is suspended on the substrate.

3. The micromechanical component as recited in claim 1, further comprising:
a frame unit provided on the substrate via which the second electrode system is suspended on the substrate.

4. The micromechanical component as recited in claim 2, wherein the first electrode system has multiple electrically decoupled electrodes which are symmetrically situated around the suspension post.

5. The micromechanical component as recited in claim 4, wherein the second electrode system has multiple electrically coupled electrodes which are symmetrically suspended around the suspension post, generally congruently with corresponding electrodes of the first electrode system.

6. The micromechanical component as recited in claim 2, wherein the second electrode system is suspended on the suspension post via multiple bending springs.

7. The micromechanical component as recited in claim 3, wherein the second electrode system is suspended on the frame unit via multiple bending springs.

8. The micromechanical component as recited in claim 1, further comprising:
a frame unit situated around the first electrode system and the second electrode system on which a third electrode system is provided.

9. The micromechanical component as recited in claim 8, wherein the third electrode system surrounds the second electrode system.

10. The micromechanical component as recited in claim 8, wherein the third electrode system and the second electrode system engage with one another, at least in certain areas, in a comb-like manner.

11. The micromechanical component as recited in claim 1, wherein the first electrode system and the second electrode system are patterned from a first and second conductive layer, respectively.

12. The micromechanical component as recited in claim 1, further comprising:
a cover plate provided above the second electrode system which specifies an entry of fluid media into the intermediate space.

13. The micromechanical component as recited in claim 12, wherein the cover plate forms an additional electrode system.

14. The micromechanical component as recited in claim 1, wherein the second electrode system has a corrugated structure.

15. The micromechanical component as recited in claim 6, wherein the bending springs have a corrugated structure.

16. The micromechanical component as recited in claim 7, wherein the bending springs have a corrugated structure.

17. The micromechanical component as recited claim 1, wherein the first electrode system is separated from the substrate by a first insulating layer.

18. A method of manufacturing a micromechanical component, comprising:
preparing a substrate;
producing of a first rigid electrode system made of a first conductive layer situated one of on or in the substrate;
producing a second insulating layer on the first rigid electrode system;
producing a second electrode system made of a second conductive layer, the second electrode system being suspended on the substrate;
producing an intermediate space between the first electrode system and the second electrode system by partial sacrificial layer etching of the second insulating layer;
whereby the second electrode system is suspended on the substrate in such an elastically deflectable manner with respect to the first electrode system that a capacitance of a capacitor formed by the first electrode system, the second electrode system, and the intermediate space may be modified.

19. The method as recited in claim 18, further comprising:
providing a suspension post on the substrate via which the second electrode system is suspended on the substrate.

20. The method as recited in claim 18, further comprising:
producing a frame unit around the first electrode system and the second electrode system, via which the second electrode system is suspended on the substrate.

21. The method as recited in claim 20, further comprising:
providing a third electrode system made of the second conductive layer on the frame unit.

22. The method as recited in claim 21, further comprising:
providing a conductive or insulating cover plate above the second electrode system which determines an entry of fluid media into the intermediate space.

23. The method as recited in claim 22, wherein before the sacrificial layer etching of the second insulating layer, a third insulating layer is produced on the second electrode system, then the cover plate is produced on the third insulating layer, and lastly the intermediate space is produced by partial sacrificial layer etching of the second insulating layer and the third sacrificial layer.

24. A microphone, comprising:
a substrate;
a first rigid electrode system situated one of on or in the substrate;
a second electrode system suspended on the substrate, an intermediate space being between the first electrode system and the second electrode system;
wherein the second electrode system is suspended on the substrate in an elastically deflectable manner with respect to the first electrode system such that a capacitance of a capacitor formed by the first electrode system, the second electrode system, and the intermediate space is modifiable.
